(19) United States
(12) Patent Application Publication
(10) Pub. No.: US 2008/0308808 A1
(43) Pub. Date: Dec. 18, 2008

(54) Thin film transistor array substrate and method for fabricating same

(75) Inventors: Chih-Chieh Hsu, Miao-Li (TW); Shuo-Ting Yan, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/214,177

(22) Filed: Jun. 16, 2008

(30) Foreign Application Priority Data
Jun. 15, 2007 (CN) 200710075055.9

(51) Int. Cl. H01L 29/786; H01L 21/336

(52) U.S. Cl. 257/61; 438/159; 257/E29.291; 257/E21.414

(57) ABSTRACT

An exemplary TFT array substrate includes an insulating substrate, a gate electrode provided on the insulating substrate, a gate insulating layer covering the gate electrode and the insulating layer, an amorphous silicon (a-Si) pattern formed on the gate insulating layer, a heavily doped a-Si pattern formed on the a-Si pattern, a source electrode formed on the gate insulating layer and the heavily doped a-Si pattern and a drain electrode formed on the gate insulating layer and the heavily doped a-Si pattern. The source electrode and the drain electrode are isolated by a slit formed between the source electrode and the drain electrode, and the a-Si pattern includes a high resistivity portion corresponding to the slit whose resistance is higher than a resistance of the a-Si material.

### FIELD OF THE INVENTION

The present invention relates to thin film transistor (TFT) array substrates used in liquid crystal displays (LCDs) and methods for fabricating these substrates, and more particularly to a TFT array substrate having a high resistivity portion, and a method for fabricating the TFT array substrate.

### BACKGROUND

A typical liquid crystal display (LCD) is capable of displaying a clear and sharp image through thousands or even millions of pixels that make up the complete image. Thus, the liquid crystal display has been applied to various electronic equipment in which messages or pictures need to be displayed, such as mobile phones and notebook computers. A liquid crystal panel is a major component of the LCD, and generally includes a TFT array substrate, a color filter substrate parallel to the TFT array substrate, and a liquid crystal layer sandwiched between the two substrates.

Referring to FIG. 15, part of a typical TFT array substrate 1 is shown. The TFT array substrate 1 includes a glass substrate 101, a gate electrode 102 formed on the glass substrate 101, a gate insulating layer 103 formed on the gate electrode 102 and the glass substrate 101, an amorphous silicon (a-Si) pattern 104 formed on the gate insulating layer 103, a heavily doped a-Si pattern 105 formed on the a-Si pattern 104, a source electrode 106 formed on the heavily doped a-Si layer 105 and the gate insulating layer 103, a drain electrode 107 formed on the heavily doped a-Si layer 105 and the gate insulating layer 103, a passivation layer 108 formed on the source electrode 106, the drain electrode 107, and the gate insulating layer 103, and a transparent conductive layer 109 formed on the passivation layer 108.

The heavily doped a-Si layer 105 defines a slit (not labeled) generally between the source electrode 106 and the drain electrode 107. The a-Si pattern 104 has a recessed portion corresponding to the slit. The a-Si pattern 104 is used as a channel layer.

When a voltage difference Vgs between the gate electrode 102 and the source electrode 106 exceeds an on-voltage Vth, the a-Si pattern 104 is activated. Thereby, current carriers can transfer between the source electrode 106 and the drain electrode 107 via the a-Si pattern 104, and a source/drain current is generated.

In theory, when the voltage difference Vgs is less than the on voltage Vth, the a-Si pattern 104 is not active such that no current carriers can transfer between the source electrode 106 and the drain electrode 107 and no current is generated. In fact, some current carriers stay in the a-Si pattern 104 when the voltage difference Vgs is less than the on-voltage Vth. When a voltage difference exists between the source electrode 106 and the drain electrode. 107, a considerably leakage current may be generated. The leakage current is liable to impair the stability and capability of the TFT array substrate 10. The greater the leakage current, the more serious the impairment.

What is needed, therefore, is a method for fabricating a TFT array substrate which can overcome the above-described deficiencies. What is also needed is a TFT array substrate fabricated by the above method.

### SUMMARY

In one preferred embodiment, a TFT array substrate includes an insulating substrate, a gate electrode provided on the insulating substrate, a gate insulating layer covering the gate electrode and the insulating layer, an amorphous silicon (a-Si) pattern formed on the gate insulating layer, a heavily doped a-Si pattern formed on the a-Si pattern, a source electrode formed on the gate insulating layer and the heavily doped a-Si pattern and a drain electrode formed on the gate insulating layer and the heavily doped a-Si pattern. The source electrode and the drain electrode are isolated by a slit formed between the source electrode and the drain electrode, and the a-Si pattern includes a high resistivity portion corresponding to the slit. An electrical resistance of the high resistivity portion being higher than an electrical resistance of the other portions of the a-Si material.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is a side cross-sectional view of part of a TFT array substrate according to an exemplary embodiment of the present invention.

FIG. 2 is a flowchart summarizing an exemplary method for fabricating the TFT array substrate of FIG. 1.

FIGS. 3 to 14 are side cross-sectional views relating to steps of the method of FIG. 3.

FIG. 15 is a side cross-sectional view of part of a conventional TFT array substrate.

### DETAILED DESCRIPTION OF PREFERRED EMBODIMENTS

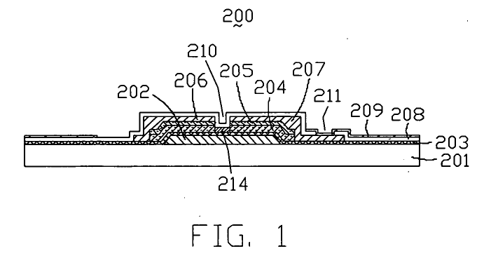

Referring to FIG. 1, a schematic, side cross-sectional view of part of a TFT array substrate 20 according to a first embodiment of the present invention is shown. The TFT array substrate 20 includes an insulating substrate 201, a gate electrode 202 formed on the insulating substrate 201, a gate insulating layer 203 formed on the gate electrode 202 and the insulating substrate 201, an a-Si pattern 204 formed on the gate insulating layer 203, a heavily doped a-Si pattern 205 formed on the a-Si pattern 204, a source electrode 206 formed on the heavily doped a-Si pattern 205 and the gate insulating layer 203, a drain electrode 207 spaced from the source electrode 206 and formed on the heavily doped a-Si pattern 205 and the gate insulating layer 203, a passivation layer 208 formed on the source electrode 206, the drain electrode 207, and the gate insulating layer 203, and a pixel electrode 209 formed on the passivation layer 208.

The pixel electrode 209 is electrically connected to the drain electrode 207 through a contact hole 211 of the passivation layer 208. A slit 210 having a certain width is formed between the source electrode 206 and the drain electrode 207, so that the source electrode 206 and the drain electrode 207 are insulated from each other. The heavily doped a-Si pattern 205 defines a slit (not labeled) thereof corresponding to the slit 210. The slit corresponds to a channel region. The two portions of the heavily doped a-Si pattern 205 are interposed between the source electrode 206 and the a-Si pattern 204, and the drain electrode 207 and the a-Si pattern 204, respectively. The heavily doped a-Si pattern 205 is used as an ohm contact layer.

The a-Si pattern 204 includes a high resistivity portion 214 corresponding to the slit 210. A resistance of the high resistivity portion 214 is higher than other portions of the a-Si pattern 204. The a-Si pattern 204 is formed of a-Si material. The high resistivity portion 214 is essentially a portion of a-Si material and formed by a process of exposing the a-Si material to ultraviolet (UV) light beams, thereby achieving a higher resistivity. Wavelengths of the UV light beams can be within a range from 90 nm (nanometers) to 400 nm.

The TFT array substrate 200 includes the a-Si pattern 204 having a high resistivity portion 214 corresponding to the slit 210. For a given voltage that may subsist between the source electrode 206 and the drain electrode 207 when current carriers remain in the a-Si layer 204, a leakage current generated between the source electrode 206 and drain electrode 207 can be effectively reduced because of the high resistance of the high resistivity portion 214. That is, the TFT array substrate 200 is apt to have a relatively small or even very small leakage current. Therefore, the TFT array substrate 200 has improved stability and capability.

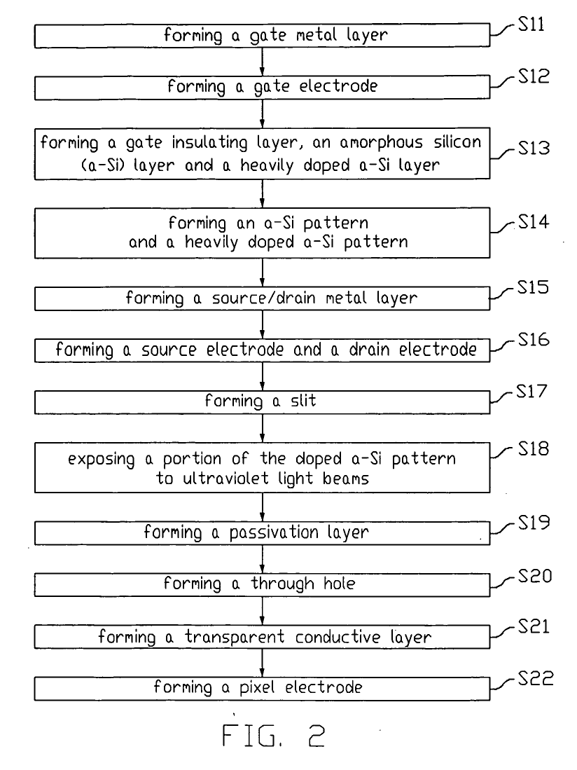

Referring to FIG. 2, this is a flowchart summarizing an exemplary method for fabricating the TFT array substrate 200. For simplicity, the flowchart and the following description are couched in terms that relate to the part of the TFT array substrate 200 shown in FIG. 1. The method includes: step S11, forming a gate metal layer; step S12, forming a gate electrode; step S13, forming a gate insulating layer, an amorphous silicon (a-Si) layer, and a heavily doped a-Si layer; step S14, forming an a-Si pattern and a heavily doped a-Si pattern; step 15, forming a source/drain metal layer; step S16, forming a source electrode and a drain electrode; step S17, forming a slit; step S18, exposing a portion of the doped a-Si pattern which is not covered by the source and drain electrodes to ultraviolet light beams; step S19, forming a passivation layer; step S20, forming a through hole; step S21, forming a transparent conductive layer; and step S22, forming a pixel electrode.

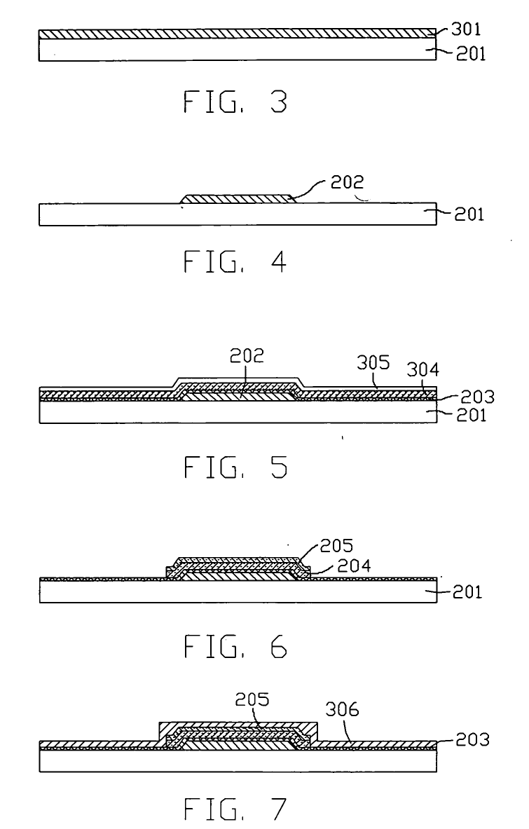

In step S11, referring to FIG. 3, an insulating substrate 201 is provided. The substrate 201 may for example be made from glass or quartz. A gate metal layer 301 and a first photo-resist layer (not labeled) are sequentially formed on the substrate 201. The gate metal layer 301 can be made from material including any one or more items selected from the group consisting of aluminum (Al), molybdenum (Mo), copper (Cu), chromium (Cr), and tantalum (Ta). The gate metal layer 301 can be single-layer or multi-layer. A first photo-mask is also provided above the first photo-resist layer.

In step S12, referring to FIG. 4, the first photo-resist layer is exposed by the first photo-mask, and then is developed, thereby forming a first photo-resist pattern (not shown). The gate metal layer 301 is etched by a wet etching method, thereby forming a pattern of the gate electrode 202, which pattern corresponds to the first photo-resist pattern. The first photo-resist pattern 92 is then removed by an acetone solution.

In step S13, referring to FIG. 5, a gate insulating layer 203 is formed on the substrate 201 and the gate electrode 202 by a chemical vapor deposition (CVD) process. In this process, silane (SiH₄) reacts with alkaline air (NH₄⁺) to obtain silicon nitride (SiNx), a material of the gate insulating layer 203. An a-Si layer 304 is deposited on the gate insulating layer 203 by a CVD process. A top layer of the a-Si layer 304 is doped, thereby forming a heavily doped a-Si layer 305. Then a second photo-resist layer (not shown) is formed on the heavily doped a-Si layer 305.

In step S14, referring to FIG. 6, an ultraviolet (UV) light source and a second photo-mask (not shown) are used to expose the second photo-resist layer. The second photo-resist layer is then developed, thereby forming a second photo-resist pattern (not shown). Using the second photo-resist pattern as a mask, portions of the heavily doped a-Si layer 305 and the a-Si layer 304 which are not covered by the third photo-resist pattern are etched away, thereby forming an a-Si pattern 204 and a heavily doped a-Si pattern 205. The a-Si pattern 204 and the heavily doped a-Si pattern 205 cooperatively constitute a semiconductor layer. The second photo-resist pattern is then removed by an acetone solution.

In step S15, referring to FIG. 7, a source/drain metal layer 306 is deposited on the gate insulating layer 203 and the heavily doped a-Si pattern 205. The source/drain metal layer 306 may be made from material including any one or more items selected from the group consisting of aluminum, aluminum alloy, molybdenum, tantalum, and molybdenum-tungsten alloy. Then a third photo-resist layer (not shown) is formed on the source/drain metal layer 306.

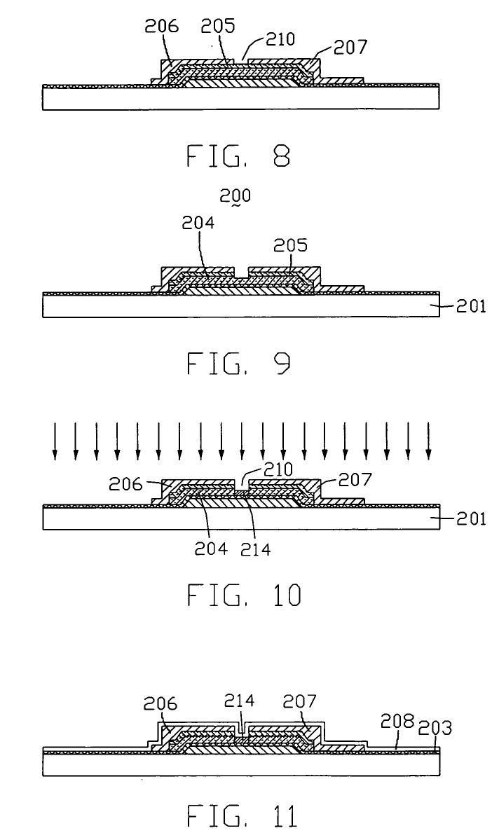

In step S16, referring to FIG. 8, the third photo-resist layer is exposed by a third photo-mask (not shown), and then is developed, thereby forming a third photo-resist pattern. The source/drain metal layer 306 is etched, thereby forming a pattern of the source electrode 206 and drain electrode 207. The source/drain electrodes 206, 207 are formed on two ends of the heavily doped a-Si layer pattern 205, with a slit formed in a middle of the a-Si layer pattern 205 between the source/drain electrodes 206, 207. The source/drain electrodes 206, 207 are symmetrically opposite each other across the slit.

In step S1 7, referring to FIG. 9, using the source/drain electrodes 206, 207 as a mask, portions of the heavily doped a-Si pattern 205 and doped a-Si pattern 204 which are not covered by the source/drain electrodes 206, 207 are etched away, thereby separating the heavily doped a-Si pattern 205 into two parts and exposing the doped a-Si pattern 204. The third photo-resist pattern is then removed by an acetone solution.

In step S18, referring to FIG. 10, an ultraviolet (UV) light source is used to expose a portion of the doped a-Si pattern 204 which is not covered by the source/drain electrodes 206, 207, thereby forming a high resistivity portion 214 corresponding to the slit between the source/drain electrodes 206, 207. The UV light source can emit UV light beams with wavelengths within a range from 90 nm to 400 nm.

In step S19, referring to FIG. 11, the passivation layer 208 and a fourth photo-resist layer (not shown) are sequentially formed on the source/drain electrodes 206, 207, the high resistivity portion 214, and the gate insulating layer 203. The passivation layer 208 is made from silicon nitride (SiNx) or silicon oxide (SiOx).

In step S20, referring to FIG. 12, the fourth photo-resist layer is exposed by a fourth photo-mask (not shown), and then is developed, thereby forming a fourth photo-resist pattern. A portion of the passivation layer 208 is etched, thereby forming the through hole 211 in the passivation layer 208. The through hole 211 is above the drain electrode 207, in order to expose a portion of the drain electrode 207. The fourth photo-resist pattern is then removed by an acetone solution.

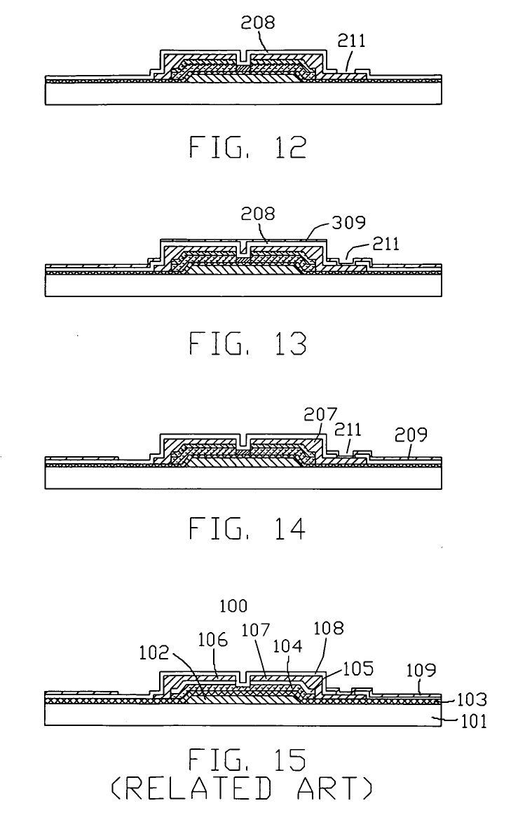

In step S21, referring to FIG. 13, a transparent conductive layer 309 and a fifth photo-resist layer (not shown) are sequentially formed on the passivation layer 208. The transparent conductive layer 309 fills the through hole 211. The transparent conductive layer 309 can be made from indium-tin-oxide (ITO) or indium-zinc-oxide (IZO).

In step S22, referring to FIG. 14, the fifth photo-resist layer is exposed by a fifth photo-mask (not shown), and then is developed, thereby forming a fifth photo-resist pattern. A portion of the transparent conductive layer 309 is etched, thereby forming a pattern of the pixel electrode 209, which pattern corresponds to the fifth photo-resist pattern. The pixel electrode 209 is electrically connected the drain electrode 207 in the though hole 211. The fifth photo-resist pattern is then removed by an acetone solution.

In the above-described exemplary method for fabricating the TFT array substrate 200, the high resistivity portion 214 formed by a UV light source exposing process is capable of reducing a leakage current when in use. Therefore the TFT array substrate 200 can provide more reliable stability and capability.

It is to be understood, however, that even though numerous characteristics and advantages of the present embodiments have been set out in the foregoing description, together with details of the structures and functions of the embodiments, the disclosure is illustrative only; and that changes may be made in detail, especially in matters of shape, size, and arrangement of parts within the principles of the invention to the full extent indicated by the broad general meaning of the terms in which the appended claims are expressed.

What is claimed is:

1. A method for fabricating a thin film transistor (TFT) array substrate, the method comprising:
providing an insulating substrate;
forming a gate electrode on the insulating substrate;
forming a gate insulating layer on the gate electrode and the insulating substrate;
forming an amorphous silicon (a-Si) pattern and a heavily doped a-Si pattern;
forming a source electrode and a drain electrode on the heavily doped a-Si pattern, comprising etching a portion of the heavily doped a-Si pattern between the source electrode and the drain electrode to exposing the a-Si pattern; and
forming a high resistivity portion in the a-Si pattern between the source electrode and the drain electrode, wherein the high resistivity portion has a higher electrical resistance than other portions of the a-Si pattern.

2. The method of claim 1, wherein the high resistivity portion is formed by a process of exposing the a-Si pattern with ultraviolet light beams.

3. The method of claim 1, wherein the source electrode and the drain electrode function as a mask in forming the high resistivity portion.

4. The method of claim 2, wherein wavelengths of the ultraviolet light beams are in a range from 90 nm to 400 nm.

5. The method of claim 1, further comprising forming a passivation layer on the source electrode, the drain electrode, the high resistivity portion, and the gate insulating layer.

6. The method of claim 5, further comprising forming a through hole in the passivation layer, wherein the drain electrode is exposed at a position corresponding to the through hole.

7. The method of claim 6, wherein forming the through hole comprises etching a portion of the passivation layer above the drain electrode.

8. The method of claim 7, further comprising forming a transparent conductive layer on the passivation layer.

9. The method of claim 8, further comprising forming a pixel electrode by etching the transparent conductive layer.

10. The method of claim 9, wherein the drain electrode is electrically connected to the pixel electrode in the through hole.

11. The method of claim 1, wherein the insulating substrate is made from one of glass and quartz.

12. The method of claim 8, wherein the transparent conductive layer is made from one of indium-tin-oxide and indium-zinc-oxide.

13. The method of claim 1, wherein the gate electrode is made from material including any one or more items selected from the group consisting of aluminum, molybdenum, copper, chromium, and tantalum.

14. The method of claim 1, wherein the source and drain electrodes are made from material including any one or more items selected from the group consisting of aluminum, aluminum alloy, molybdenum, tantalum, and molybdenum-tungsten alloy.

15. The method of claim 1, wherein forming the a-Si pattern and the heavily doped a-Si pattern comprises forming an a-Si layer on the gate insulating layer, doping a top layer of the a-Si layer into a heavily doped a-Si layer, using a mask to expose the a-Si layer and the heavily doped a-Si layer, and etching portions of the heavily doped a-Si layer and the a-Si layer.

16. A thin film transistor array substrate comprising:
an insulating substrate;
a gate electrode on the insulating substrate;
a gate insulating layer covering the gate electrode and the insulating substrate;
an amorphous silicon (a-Si) pattern formed on the gate insulating layer;
a heavily doped a-Si pattern formed on the amorphous a-Si pattern;
a source electrode formed on the gate insulating layer and the heavily doped a-Si pattern; and
a drain electrode formed on the gate insulating layer and the heavily doped a-Si pattern;
wherein the source electrode and the drain electrode are isolated from each other by a slit therebetween, and the a-Si pattern comprises a high resistivity portion corresponding to the slit, an electrical resistance of the high resistivity portion being higher than an electrical resistance of other portions of the a-Si pattern.

17. The thin film transistor array substrate of claim 16, wherein the high resistivity portion is an ultraviolet light beam exposed portion of the a-Si pattern.

18. The thin film transistor array substrate of claim 17, wherein the slit between the source electrode and the drain electrode also spans through at least part of the heavily doped a-Si pattern.
